(19) United States
(12) Patent Application Publication
(10) Pub. No.: US 2024/0387649 A1
(43) Pub. Date: Nov. 21, 2024

(54) SEMICONDUCTOR DEVICE

(71) Applicant: Renesas Electronics Corporation, Tokyo (JP)

(72) Inventor: Kodai OZAWA, Tokyo (JP)

(21) Appl. No.: 18/613,754

(22) Filed: Mar. 22, 2024

(30) Foreign Application Priority Data
May 16, 2023 (JP) 2023-080585

(51) Int. Cl. H01L 29/40; H01L 29/739; H01L 29/861

(52) U.S. Cl. CPC H01L 29/408; H01L 29/7393; H01L 29/861

(57) ABSTRACT

A semiconductor device capable of suppressing variation in breakdown voltage is provided. The semiconductor device includes a semiconductor substrate, an insulating film, a first electrode and a second electrode, and a semi-insulating film. The semiconductor substrate has a first surface. The semiconductor substrate has, in plan view, an element region and a termination region surrounding the element region. The semiconductor substrate has a first impurity region formed on a first surface in the termination region. The semi-insulating film is disposed so as to extend over the insulating film between the first electrode and the second electrode in plan view. The semi-insulating film includes silicon and nitrogen.

### CROSS-REFERENCE TO RELATED APPLICATIONS

The disclosure of Japanese Patent Application No. 2023-080585 filed on May 16, 2023, including the specification, drawings and abstract is incorporated herein by reference in its entirety.

### BACKGROUND

The present disclosure relates to a semiconductor device.

For example, Japanese Unexamined Patent Application Publication No. 2022-074323 (Patent Document 1) describes a semiconductor device. The semiconductor device according to Patent Document 1 includes a semiconductor substrate, a first electrode, a second electrode, an insulating film, and a semi-insulating film. The semiconductor substrate has a first region and a second region surrounding the first region in plan view. The semiconductor substrate has a first surface and a second surface opposite the first surface in a direction of thickness of the semiconductor substrate. The semiconductor substrate includes an impurity region formed on the first surface of the first region. The insulating film covers the first surface in the second region. The first electrode is opposed to the impurity region with an insulating film interposed therebetween. The second electrode is disposed on the insulating film so as to surround the first electrode while being separated from the first electrode in a plan view. The semi-insulating film is disposed so as to extend across the insulating film between the first electrode and the second electrode.

There are disclosed techniques listed below.
[Patent Document 1] Japanese Unexamined Patent Application Publication No. 2022-074323

### SUMMARY

In the semiconductor device described in Patent Document 1, the breakdown voltage may fluctuate each time a voltage is applied. Other objects and novel features will become apparent from the description of this specification and the accompanying drawings.

A semiconductor device of the present disclosure comprises a semiconductor substrate, an insulating film, a first electrode and a second electrode, and a semi-insulating film. The semiconductor substrate includes a first surface. The semiconductor substrate includes, in plan view, an element region and a termination region the surrounding element region. The semiconductor substrate includes a first impurity region formed on the first surface in the termination region. The insulating film covers the first surface in the termination region. The first electrode is electrically connected to the first impurity region and faces the first impurity region with the insulating film interposed therebetween. The second electrode is disposed on the insulating film so as to surround the first electrode while being spaced apart from the first electrode in a plan view. The semi-insulating film is disposed so as to extend across the insulating film between the first electrode and the second electrode in a plan view. The semi-insulating film includes silicon and nitrogen. The ratio of the number of atoms of silicon to the sum of the number of atoms of silicon and the number of atoms of nitrogen in the semi-insulating film is 0.64 or more.

According to the semiconductor device of the present disclosure, variation in the breakdown voltage can be suppressed.

### BRIEF DESCRIPTION OF THE DRAWINGS

FIG. 1 is a plan view of the semiconductor device DEV1.

FIG. 2 is a cross-sectional view of the semiconductor device DEV1 in II-II of FIG. 1.

FIG. 3 is a manufacturing process diagram of the semiconductor device DEV1.

FIG. 4 is a cross-sectional view describing the preparation process S1.

FIG. 5 is a cross-sectional view for explaining the epitaxial growth process S2.

FIG. 6 is a cross-sectional view illustrating a first insulating film forming step S3.

FIG. 7 is a cross-sectional view describing the impurity-region forming process S4.

FIG. 8 is a cross-sectional view for explaining a second insulating film forming step S5.

FIG. 9 is a cross-sectional view illustrating a first electrode-forming step S6.

FIG. 10 is a cross-sectional view illustrating the step of forming the semi-insulating film S7.

FIG. 11 is a cross-sectional view illustrating a second electrode-forming step S8.

FIG. 12 is a graph showing the relationship between the ratio of the number of atoms of silicon to the sum of the number of atoms of silicon and the number of atoms of nitrogen in the semi-insulating film SIF and the number of silicon-hydrogen bonds.

FIG. 13 is a graph showing the relationship between the number of measurements of the breakdown voltage and the breakdown voltage.

FIG. 14 is a graph showing the relationship between the refractive index of the semi-insulating film SIF and the ratio of the number of atoms of silicon to the sum of the number of atoms of silicon and the number of atoms of nitrogen in the semi-insulating film SIF.

FIG. 15 is a graph showing the relationship between the refractive index of the semi-insulating film SIF and variation in the thickness T1 of the semi-insulating film SIF.

FIG. 16 is a cross-sectional view of the semiconductor device DEV2.

FIG. 17 is a manufacturing process diagram of the semiconductor device DEV2.

FIG. 18 is a cross-sectional view of the semiconductor device DEV3.

FIG. 19 is a manufacturing process diagram of the semiconductor device DEV3.

FIG. 20 is a cross-sectional view describing the first impurity-region forming step S10.

FIG. 21 is a cross-sectional view for explaining the first insulating film forming step S3 in the manufacturing method of the semiconductor device DEV3.

FIG. 22 is a cross-sectional view describing the second impurity-region forming step S11.

FIG. 23 is a cross-sectional view of the semiconductor device DEV4.

FIG. 24 is a manufacturing process diagram of the semiconductor device DEV4.

FIG. 25 is a cross-sectional view for explaining the first insulating film forming step S3 in the manufacturing method of the semiconductor device DEV4.

FIG. 26 is a cross-sectional view for explaining a third impurity-region forming step S12.

FIG. 27 is a cross-sectional view describing the fourth impurity-region forming step S13.

### DETAILED DESCRIPTION

Details of embodiments of the present disclosure will be described with reference to the drawings. In the following drawings, the same or corresponding parts are denoted by the same reference numerals, and redundant description will not be repeated.

### First Embodiment

A semiconductor device DEV1 according to a first embodiment will be described.

### <Configuration of the Semiconductor Device DEV1>

The configuration of the semiconductor device DEV1 will be described below.

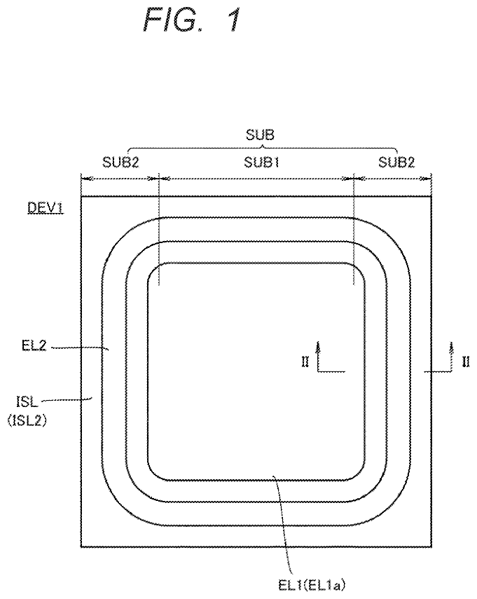

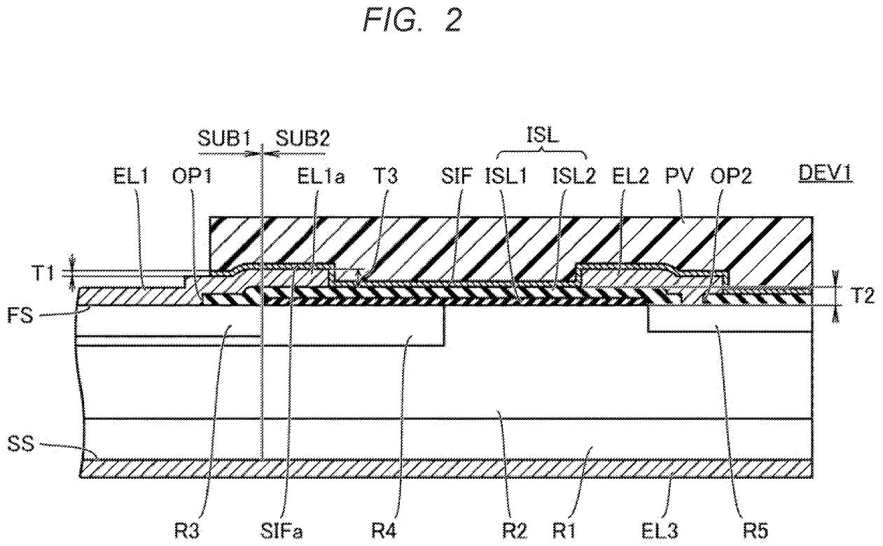

FIG. 1 is a plan view of the semiconductor device DEV1. FIG. 2 is a cross-sectional view of the semiconductor device DEV1 in II-II of FIG. 1. As shown in FIGS. 1 and 2, the semiconductor device DEV1 has a semiconductor substrate SUB. The semiconductor substrate SUB has a first surface FS and a second surface SS opposite the first surface FS in the thickness direction of the semiconductor substrate SUB. The constituent of the semiconductor substrate SUB is, for example, single-crystal Silicon (Si).

The semiconductor substrate SUB has an element region SUB1 and a termination region SUB2. The termination region SUB2 surrounds the element region SUB1 in plan view.

The semiconductor substrate SUB includes an impurity region R1, an impurity region R2, an impurity region R3, an impurity region R4, and an impurity region R5. The conductivity type of the impurity region R1 and the conductivity type of the impurity region R2 are the first conductivity type. The first conductivity type is, for example, n-type. The conductivity type of the impurity region R3 and the conductivity type of the impurity region R4 are the second conductivity type. The second conductivity type is, for example, p-type. The conductivity type of the impurity-region R5 is the first conductivity type or the second conductivity type.

The impurity region R1 is formed on the second surface SS. The impurity region R2 is formed on the first surface FS. The impurity region R2 is in contact with the impurity region R1 on the other side of the first surface FS. The impurity region R1 and the impurity region R2 form a cathode of, for example, FRD (Fast Recovery Diode).

The impurity region R3 is formed on the first surface FS of the element region SUB1. The impurity region R4 is formed on the first surface of the termination region SUB2. The impurity region R3 is pn bonded to the impurity region R2. The impurity region R3 is, for example, an anode of an FRD. As described above, in the semiconductor device DEV1, FRD is formed in the element region SUB1.

The impurity region R4 is formed on the first surface FS in the termination region SUB2. The impurity region R4 extends over a boundary between the element region SUB1 and the termination region SUB2 in a plan view. The impurity region R4 surrounds the impurity region R3 in plan view. The impurity region R4 is in contact with the impurity region R3. That is, the impurity region R4 is electrically connected to the impurity region R3. The impurity region R4 is pn bonded to the impurity region R2. The impurity concentration in the impurity region R4 is lower than the impurity concentration in the impurity region R3. That is, the impurity region R4 forms a RESURF (REduced SUrface Field) structure. The impurity region R5 is formed on the first surface FS in the termination region SUB2. The impurity region R5 surrounds the impurity region R4 in plan view. The impurity region R5 is separated from the impurity region R4.

The semiconductor device DEV1 further includes an insulating film ISL. The insulating film ISL is disposed on the first surface FS. The insulating film ISL covers at least the first surface FS in the termination region SUB2. The insulating film ISL partially covers the first surface FS in the element region SUB1. An opening OP1 and an opening OP2 are formed in the insulating film ISL. The opening OP1 is formed on the impurity regions R3. The opening OP2 is formed on the impurity regions R5.

The insulating film ISL includes a first insulating film ISL1 and a second insulating film ISL2. The first insulating film ISL1 and the second insulating film ISL2 are made of, for example, silicon oxide (SiO₂). The first insulating film ISL1 covers the first surface FS between the impurity region R3 and the impurity region R5. The second insulating film ISL2 covers the first insulating film ISL1. Therefore, a step is formed in the upper surface of the insulating film ISL.

The semiconductor device DEV1 further includes a first electrode EL1 and a second electrode EL2. The first electrode EL1 and the second electrode EL2 are made of, for example, aluminum (Al) or an aluminum alloy.

The first electrode EL1 has an outer peripheral edge portion EL1a. The outer peripheral edge portion EL1a faces the impurity regions R4 with the insulating film ISL interposed therebetween. The peripheral edge EL1a functions as a field plate. The first electrode EL1 is connected to the impurity region R3 via the opening portion OP1. As described above, since the impurity region R3 is in contact with the impurity region R4, the first electrode EL1 is electrically connected to the impurity region R4. The second electrode EL2 is disposed on the insulating film ISL. The second electrode EL2 surrounds the first electrode EL1 in plan view. The second electrode EL2 is spaced apart from the first electrode EL1. The second electrode EL2 is connected to the impurity region R5 via the opening portion OP2. The second electrode EL2 is set to, for example, a grounding potential.

The semiconductor device DEV1 further includes a semi-insulating film SIF. The semi-insulating film SIF includes silicon and nitrogen (N). The semi-insulating film SIF is composed of, for example, a mixed crystal of silicon nitride (Si₃N₄) and amorphous silicon. From another point of view, a portion of the silicon contained in the semi-insulating film SIF is bonded to hydrogen.

In the semi-insulating film SIF, the ratio of the number of atoms of silicon to the sum of the number of atoms of silicon and the number of atoms of nitrogen (i.e., the number of atoms of silicon divided by the sum of the number of atoms of silicon and the number of atoms of nitrogen) is 0.64 or more. In the semi-insulating film SIF, the ratio of the number of atoms of silicon to the sum of the number of atoms of silicon and the number of atoms of nitrogen may be 0.74 or less. The ratio of the number of atoms of silicon to the sum of the number of atoms of silicon and the number of atoms of nitrogen in the semi-insulating film SIF is measured by XPS(X-ray Photoelectron Spectroscopy).

The refractive index of the semi-insulating film SIF is, for example, 2.55 or more. The refractive index of the semi-insulating film SIF is, for example, 2.90 or less. The refractive index of the semi-insulating film SIF is measured optically using a spectroscopic ellipsometer.

The semi-insulating film SIF is disposed so as to extend across the insulating film ISL between the first electrode EL1 and the second electrode EL2. The semi-insulating film SIF has an inner peripheral edge portion SIFa. The inner peripheral edge portion SIFa is disposed on the outer peripheral edge portion EL1a. The semi-insulating film SIF covers the second electrode EL2.

The thickness T1 of the semi-insulating film SIF is, for example, equal to or greater than 50 nm and equal to or less than 1000 nm. The variation in the thickness T1 is, for example, 0.02 or less. The variation in the thickness T1 is defined as the larger value of:
(i) the value obtained by dividing
the value obtained by (subtracting the average value of the thickness T1 from the maximum value of the thickness T1)
by the average value of the thickness T1, and
(ii) the value obtained by dividing
the value obtained by (subtracting the minimum value of the thickness T1 from the average value of the thickness T1)
by the average value of the thickness T1.

The thickness T2 of the insulating film ISL is, for example, 0.5 μm (micrometers) or more and 3.0 μm (micrometers) or less. The thickness T2 is measured at a portion between the first surface FS and the semi-insulating film SIF. The thickness T3 of the first electrode EL1 and the second electrode EL2 is, for example, 2.0 μm (micrometers) or more and 6.0 μm (micrometers) or more from the viewpoint of securing margins at the time of wire bonding.

The semiconductor device DEV1 further includes a thirdelectrode EL3. The third electrode EL3 may be made of aluminum or an aluminum alloy. The third electrode EL3 is disposed on the second surface SS.

The semiconductor device DEV1 further comprises a passivation film PV. The passivation film PV is made of, for example, polyimide. The passivation film PV is disposed on the semi-insulating film SIF.

### <Manufacturing Method of the Semiconductor Device DEV1>

A manufacturing method of the semiconductor device DEV1 is described below.

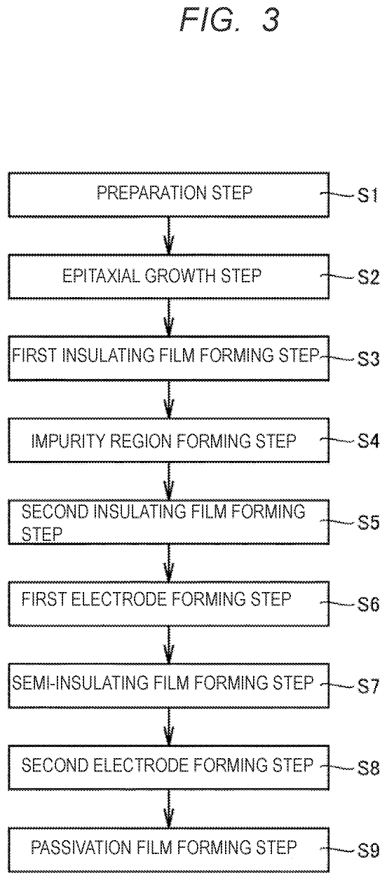

FIG. 3 is a manufacturing process diagram of the semiconductor device DEV1. As shown in FIG. 3, the manufacturing method of the semiconductor device DEV1 includes a preparation step S1, an epitaxial growth step S2, a first insulating film forming step S3, an impurity region forming step S4, a second insulating film forming step S5, a first electrode forming step S6, a semi-insulating film forming step S7, a second electrode forming step S8, and a passivation film forming step S9.

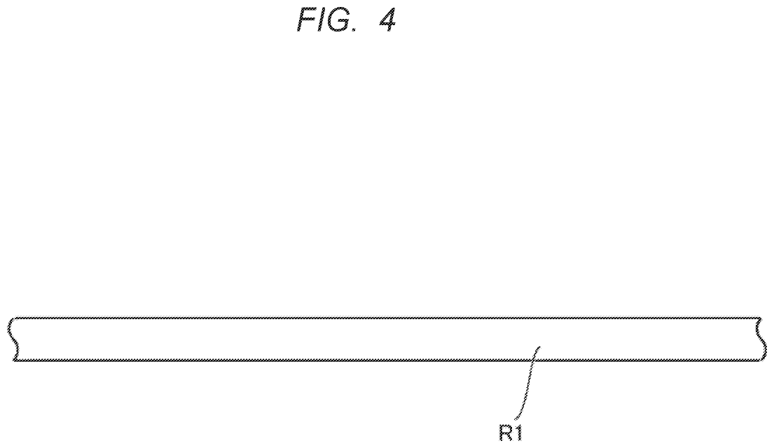

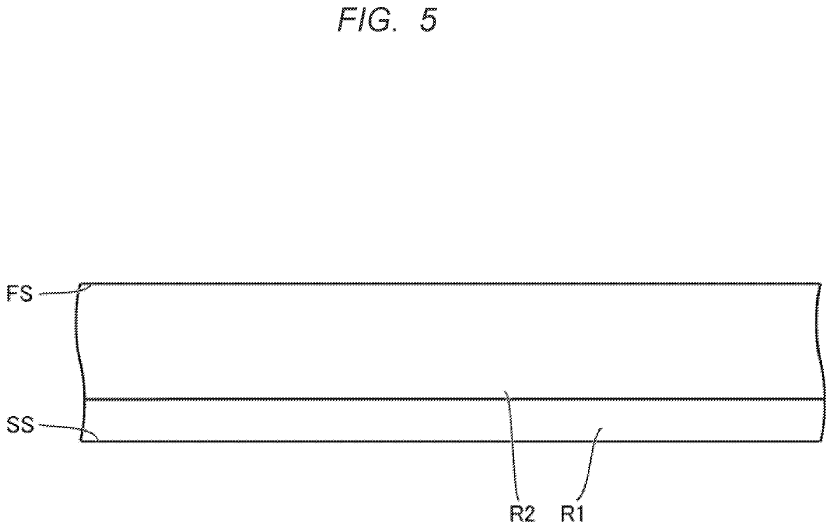

FIG. 4 is a cross-sectional view illustrating a preparation step S1. As shown in FIG. 4, in the preparation process S1, a semiconductor substrate SUB is prepared. At this stage, the semiconductor substrate SUB has only the impurity-region R1. FIG. 5 is a cross-sectional view illustrating an S2 of an epitaxial growth process. As shown in FIG. 5, in the epitaxial growth process S2, the impurity region R2 is epitaxially grown on the impurity region R1. The impurity-region R2 is formed by, for example, CVD (Chemical Vapor Deposition).

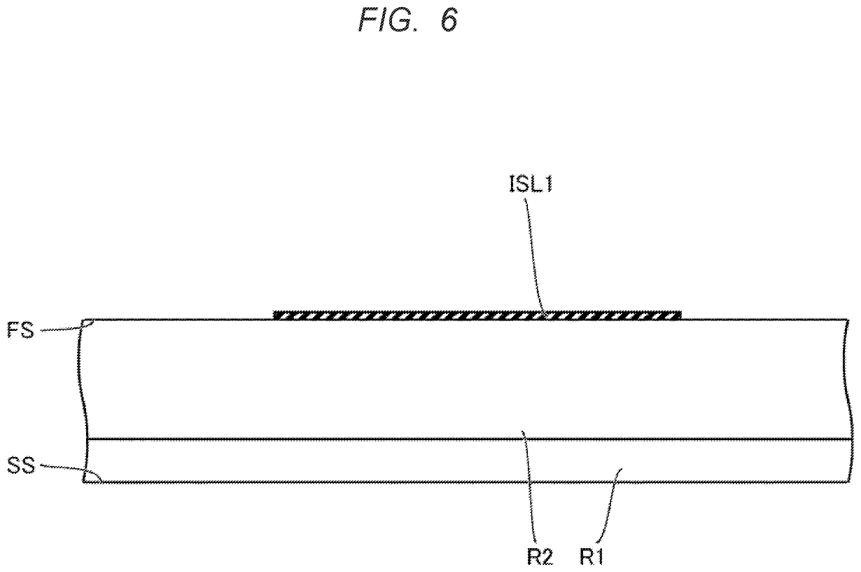

FIG. 6 is a cross-sectional view illustrating the first insulating film forming step S3. As shown in FIG. 6, in the first insulating film forming step S3, the first insulating film ISL1 is formed. In the first insulating film forming step S3, first, a constituent material of the first insulating film ISL1 is formed on the first surface FS by a thermal oxidation method or a CVD method. Second, a constituent material of the formed first insulating film ISL1 is etched using a resist pattern formed by photolithography.

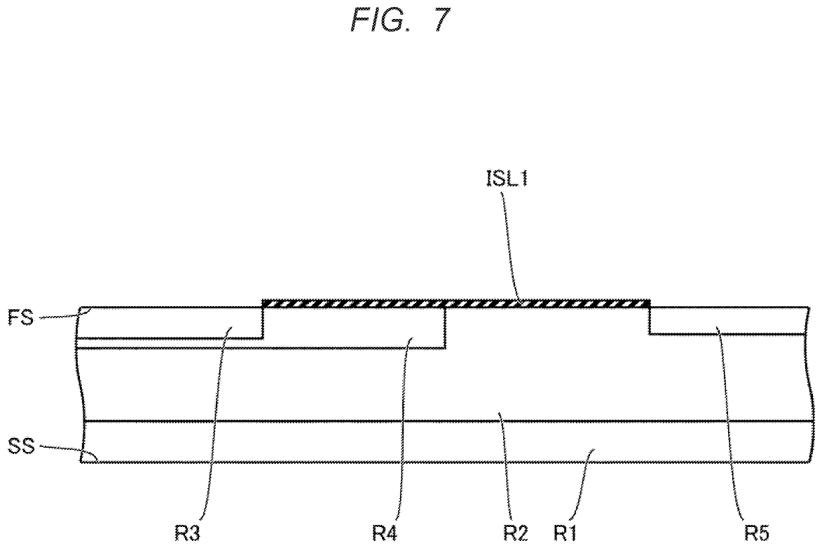

FIG. 7 is a cross-sectional view for explaining the impurity-region forming step S4. As illustrated in FIG. 7, in the impurity region forming step S4, the impurity region R3, the impurity region R4, and the impurity region R5 are formed. In the impurity-region forming step S4, first, a resist pattern is formed on the first surface FS and the first insulating film ISL1 by a photolithography method. Second, ion-implantation is performed from the first surface FS side using the resist pattern as a mask. Third, the resist pattern is removed. Fourth, the implanted impurity ions are thermally diffused by annealing the semiconductor substrate SUB. As a result, the impurity regions R4 are formed. By the same process, the impurity region R3 and the impurity region R5 are also formed.

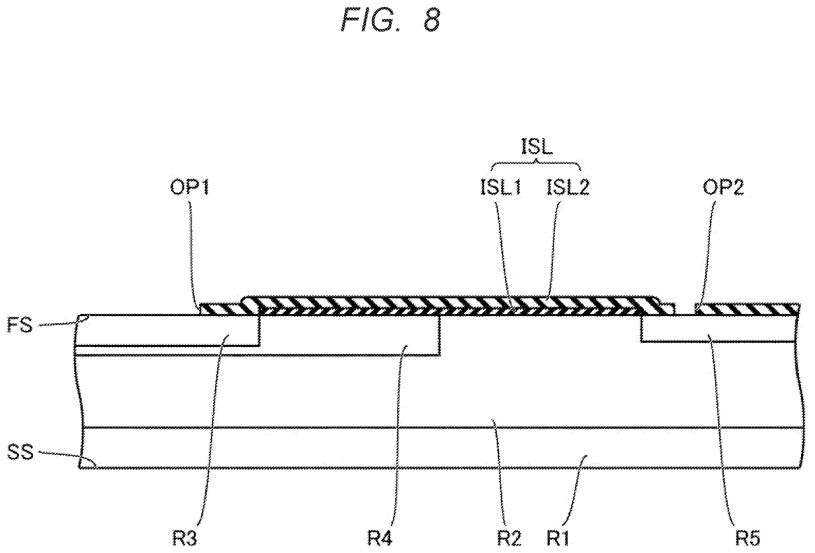

FIG. 8 is a cross-sectional view illustrating the second insulating film forming step S5. As shown in FIG. 8, in the second insulating film forming step S5, the second insulating film ISL2 is formed. In the second insulating film forming step S5, first, a constituent material of the second insulating film ISL2 is formed to cover the first insulating film ISL1 by, for example, a CVD method. Second, a constituent material of the formed second insulating film ISL2 is etched using a resist pattern formed by photolithography.

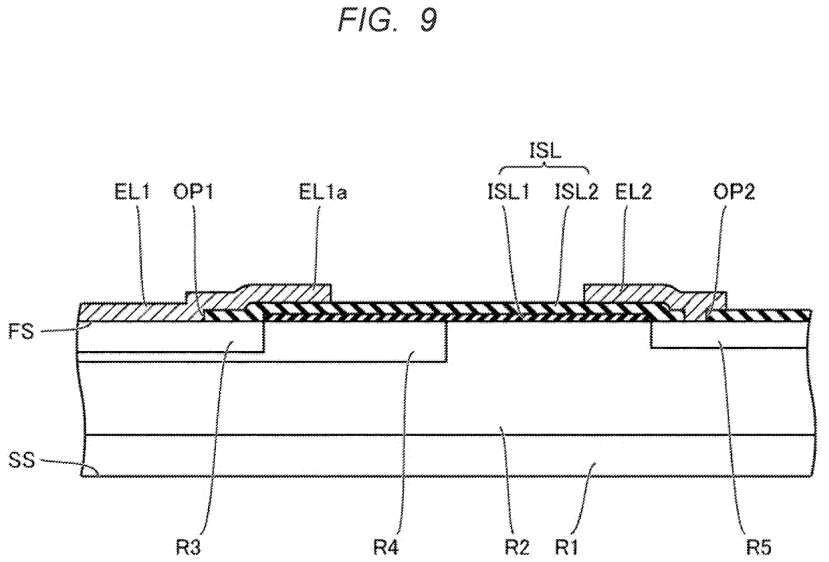

FIG. 9 is a cross-sectional view for explaining the first electrode-forming step S6. As shown in FIG. 9, in the first electrode forming step S6, the first electrode EL1 and the second electrode EL2 are formed. In the first electrode forming step S6, first, a constituent material of the first electrode EL1 (second electrode EL2) is deposited on the first surface FS and on the insulating film ISL by, for example, a sputtering method. Second, a constituent material of the formed first electrode EL1 (second electrode EL2) is etched using a resist pattern formed by photolithography.

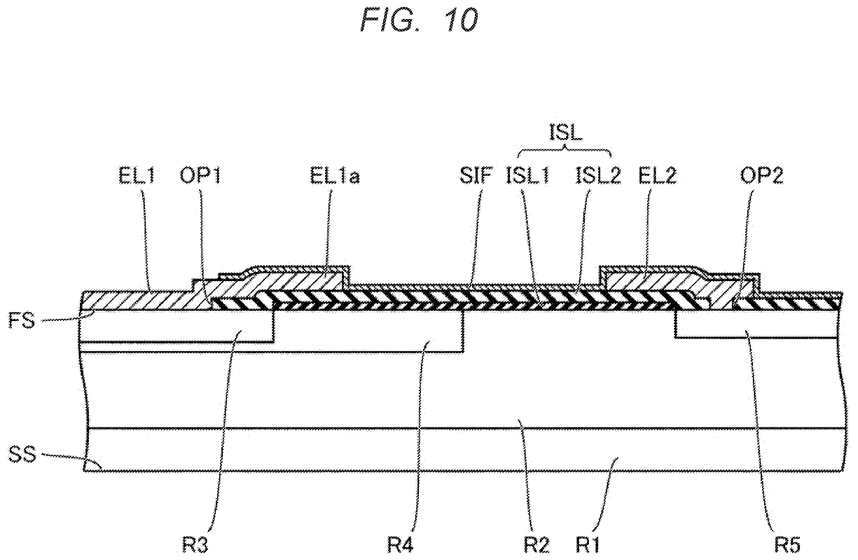

FIG. 10 is a cross-sectional view illustrating S7 of the semi-insulating film forming step. As shown in FIG. 10, in the semi-insulating film forming step S7, the semi-insulating film SIF is formed. In the semi-insulating film forming step S7, first, a constituent material of the semi-insulating film SIF is formed by, for example, a CVD method so as to cover the first electrode EL1, the second electrode EL2, and the insulating film ISL. Second, a constituent material of the formed semi-insulating film SIF is patterned by etching using a resist pattern formed by photolithography. The ratio of the number of atoms of silicon to the sum of the number of atoms of silicon and the number of atoms of nitrogen in the semi-insulating film SIF is obtained by adjusting the flow rate ratio of monosilane (SiH₄) and nitrogen gas (N₂) in the reactive gas when CVD method is performed. As the flow rate of the monosilane divided by the flow rate of the nitrogen gas increases, the ratio of the number of atoms of the silicon to the sum of the number of atoms of the silicon and the number of atoms of the nitrogen in the semi-insulating film SIF increases.

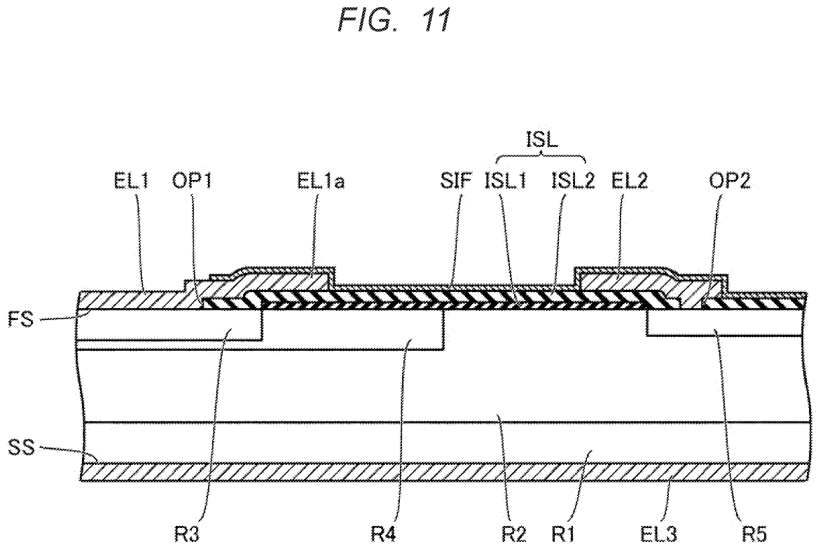

FIG. 11 is a cross-sectional view for explaining the second electrode-forming step S8. As shown in FIG. 11, in the second electrode forming step S8, a constituent material of the third electrode EL3 is formed on the second surface SS by, for example, sputtering to form the third electrode EL3. In the passivation film forming step S9, a passivation film PV is formed. In the passivation film forming step S9, first, a constituent material of the passivation film PV is formed so as to cover the semi-insulating film SIF and the first electrode EL1. Second, a formed constituent material of the passivation film PV is patterned by photolithography. As a result, the structure of the semiconductor device DEV1 shown in FIGS. 1 and 2 is formed.

In the above-described manufacturing method embodiment, in the preparation step S1, the semiconductor substrate SUB having only the impurity region R1 is provided, but in the preparation step S1, the semiconductor substrate SUB having only the impurity region R2 may be provided. In this case, the epitaxial growth step S2 is not performed, and the impurity region R1 is formed by ion-implantation from the second surface SS. The impurity region R1 is formed by ion-implantation prior to the second electrode-forming step S8.

### Modified Example

In the above description, an FRD is formed in the element region SUB1, but a semiconductor element other than an FRD may be formed in the element region SUB1. For example, an IGBT (Insulated Gate Bipolar Transistor) may be formed in the element region SUB1.

### <Effect of the Semiconductor Device DEV1>

Below, the effectiveness of the semiconductor device DEV1 will be described in comparison with the semiconductor device according to the comparative example. The configuration of the semiconductor device according to the comparative example is the same as the configuration of the semiconductor device DEV1 except that the ratio of the number of atoms of silicon to the sum of the number of atoms of silicon and the number of atoms of nitrogen in the semi-insulating film SIF is less than 0.64.

In the semiconductor device DEV1 and the semiconductor device according to the comparative example, since the semi-insulating film SIF is semi-insulating, a weak leakage current flows through the semi-insulating film SIF, so that the electric field is relaxed in the semiconductor substrate SUB facing the semi-insulating film SIF with the insulating film ISL interposed therebetween, and the breakdown voltage is improved. At this time, electrons are induced and trapped in the semi-insulating film SIF.

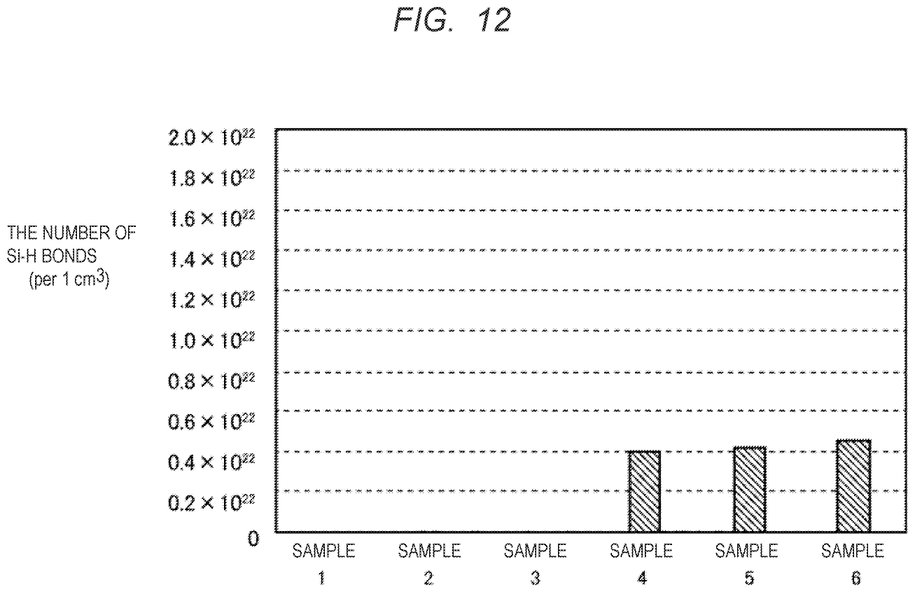

FIG. 12 is a graph showing the relationship between (i) the ratio of the number of atoms of silicon to the sum of the number of atoms of silicon and the number of atoms of nitrogen in the semi-insulating film SIF and (ii) the number of silicon-hydrogen bonds. The graph of FIG. 12 was s obtained by performing FT-IR (Fourier Transformation InfraRed spectroscopy) analysis on sample 1 to sample 6 of the semi-insulating film SIF.

The ratio of the number of atoms of silicon to the sum of the number of atoms of silicon and the number of atoms of nitrogen in each sample is greater in the order of Sample 1, Sample 2, Sample 3, Sample 4, Sample 5, and Sample 6. The ratio of the number of atoms of silicon to the sum of the number of atoms of silicon and the number of atoms of nitrogen in sample 1 to sample 3 is less than 0.64, and the ratio of the number of atoms of silicon to the sum of the number of atoms of silicon and the number of atoms of nitrogen in sample 4 to sample 6 is 0.64 or more.

As shown in FIG. 12, no silicon-hydrogen bonds were detected in samples 1 to 3. On the other hand, a peak derived from silicon-hydrogen bonds has been detected in samples 4 to 6. In other words, the semiconductor device DEV1 contains amorphous silicon in the semi-insulating film SIF, while the semiconductor device according to the comparative example does not contain amorphous silicon in the semi-insulating film SIF.

In the semiconductor device according to the comparative example, since the semi-insulating film SIF does not contain amorphous silicon through which a current easily flows, electrons induced and trapped in the semi-insulating film SIF hardly escape from the semi-insulating film SIF. Electrons induced and trapped in the semi-insulating film SIF cause the breakdown voltage to fluctuate. On the other hand, in the semiconductor device DEV1, since the semi-insulating film SIF contains amorphous silicon through which a current easily flows, the induced and trapped electrons flow to the second electrode EL2 and easily escape from the semi-insulating film SIF. Therefore, according to the semiconductor device DEV1, variation in the breakdown voltage can be suppressed.

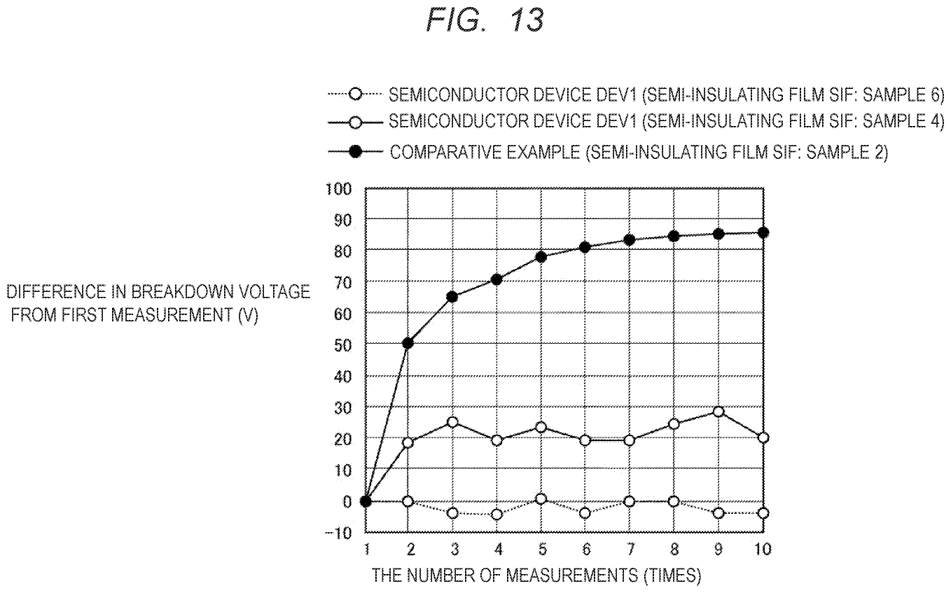

FIG. 13 is a graph showing a relationship between the number of times of measurement of the breakdown voltage and the breakdown voltage. In FIG. 13, sample 2 in FIG. 12 is applied as the semi-insulating film SIF of the semiconductor device according to the comparative example, and sample 4 or sample 6 are applied as the semi-insulating film SIF in the semiconductor device DEV1. The vertical axis of the graph of FIG. 13 shows the difference between the breakdown voltage in the n-th measurement (n is an integer of 1 or more and 10 or less) and the breakdown voltage in the first measurement. Since the value of the vertical axis in the first measurement is (withstand voltage in the first measurement)−(withstand voltage in the first measurement), it is 0. As shown in FIG. 13, in the semiconductor device according to the comparative example in which the ratio of the number of atoms of silicon to the sum of the number of atoms of silicon and the number of atoms of nitrogen in the semi-insulating film SIF is less than 0.64, the breakdown voltage greatly fluctuates as the number of times of measuring increases. On the other hand, in the semiconductor device DEV1 where the ratio of the number of atoms of silicon to the sum of the number of atoms of silicon and the number of atoms of nitrogen in the semi-insulating film SIF is 0.64 or more, even if the number of times of measuring is increased, the variation in the breakdown voltage is small.

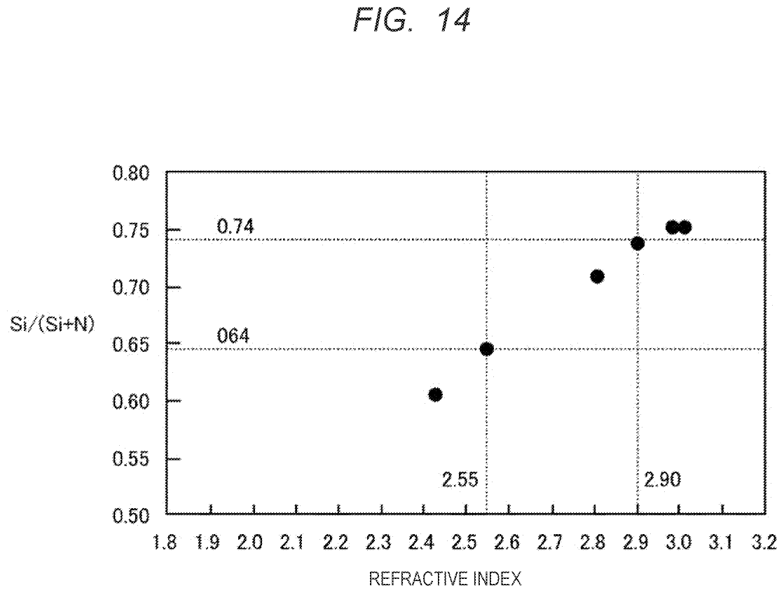

FIG. 14 is a graph showing the relationship between the refractive index of the semi-insulating film SIF and the ratio of the number of atoms of silicon to the sum of the number of atoms of silicon and the number of atoms of nitrogen in the semi-insulating film SIF. As shown in FIG. 14, as the refractive index of the semi-insulating film SIF increases, the ratio of the number of atoms of silicon to the sum of the number of atoms of silicon and the number of atoms of nitrogen in the semi-insulating film SIF increases. More specifically, if the ratio of the number of atoms of silicon to the sum of the number of atoms of silicon and the number of atoms of nitrogen in the semi-insulating film SIF is 0.64 or more, the refractive index of the semi-insulating film SIF is 2.55 or more. Further, if the ratio of the number of atoms of silicon to the sum of the number of atoms of silicon and the number of atoms of nitrogen in the semi-insulating film SIF is 0.74 or less, the refractive index of the semi-insulating film SIF is 2.90 or less. As described above, by setting the refractive index of the semi-insulating film SIF to 2.55 or more, the semiconductor device DEV1 can suppress variations in the breakdown voltage.

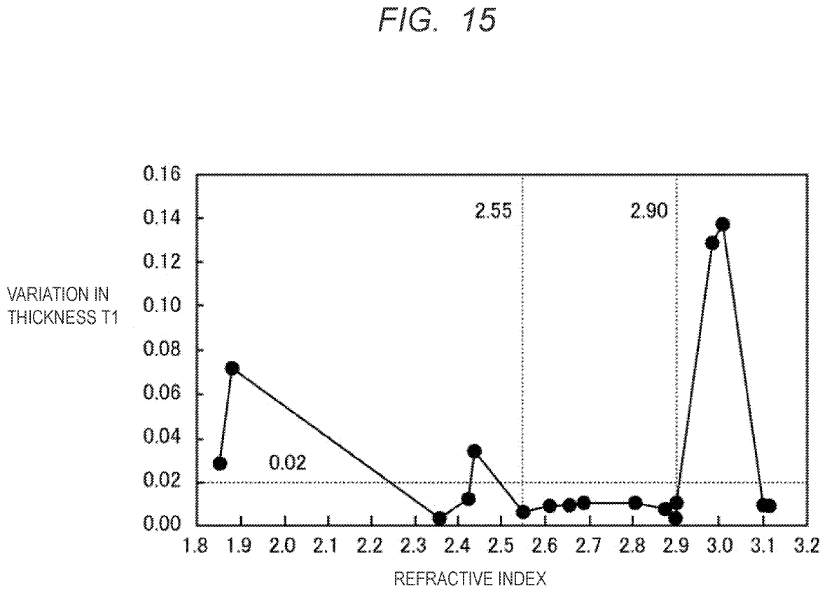

FIG. 15 is a graph showing the relationship between the refractive index of the semi-insulating film SIF and the variation in the thickness T1 of the semi-insulating film SIF. As shown in FIG. 15, when the refractive index of the semi-insulating film SIF is greater than 2.90, that is, when the ratio of the number of atoms of silicon to the sum of the number of atoms of silicon and the number of atoms of nitrogen in the semi-insulating film SIF is greater than 0.74, the variation in the thickness T1 increases. On the other hand, when the ratio of the number of atoms of silicon to the sum of the number of atoms of silicon and the number of atoms of nitrogen in the semi-insulating film SIF is not less than 0.64 and not more than 0.74, the variation in the thickness T1 is not more than 0.02. Therefore, by setting the ratio of the number of atoms of silicon to the sum of the number of atoms of silicon and the number of atoms of nitrogen in the semi-insulating film SIF to 0.64 or more and 0.74 or less, variations in the thickness T1 can be suppressed while suppressing variations in the breakdown voltage.

As the thickness T1 increases, current tends to flow through the semi-insulating film SIF, and the induced/trapped electrons further tend to escape. On the other hand, if the thickness T1 is too large, the semi-insulating film SIF is hard, so that cracks tend to occur in the semi-insulating film SIF. Therefore, by setting the thickness T1 to be equal to or greater than 50 nm and equal to or less than 1000 nm, it is possible to suppress the occurrence of cracks in the semi-insulating film SIF while suppressing the breakdown voltage variation.

As the thickness T2 increases, the capacitance composed of the semi-insulating film SIF, the insulating film ISL, and the semiconductor substrate SUB decreases, and the variation in the breakdown voltage is suppressed. On the other hand, if the thickness T2 is too large, the embeddability of the first electrode EL1 and the second electrode EL2 deteriorates. If the thickness T2 is too large, the step formed in the upper surface of the insulating film ISL becomes large, and cracks tend to occur in the semi-insulating film SIF due to the step. Therefore, by setting the thickness T2 to 0.5 μm (micrometers) or more and 3.0 μm (micrometers) or less, it is possible to suppress the occurrence of cracks in the semi-insulating film SIF and deterioration of the embeddability of the first electrode EL1 and the second electrode EL2 while suppressing the breakdown voltage variation.

### Second Embodiment

A semiconductor device DEV2 according to a second embodiment will be described. Here, differences from the semiconductor device DEV1 will be mainly described, and redundant description will not be repeated.

### <Configuration of the Semiconductor Device DEV2>

The configuration of the semiconductor device DEV2 will be described below.

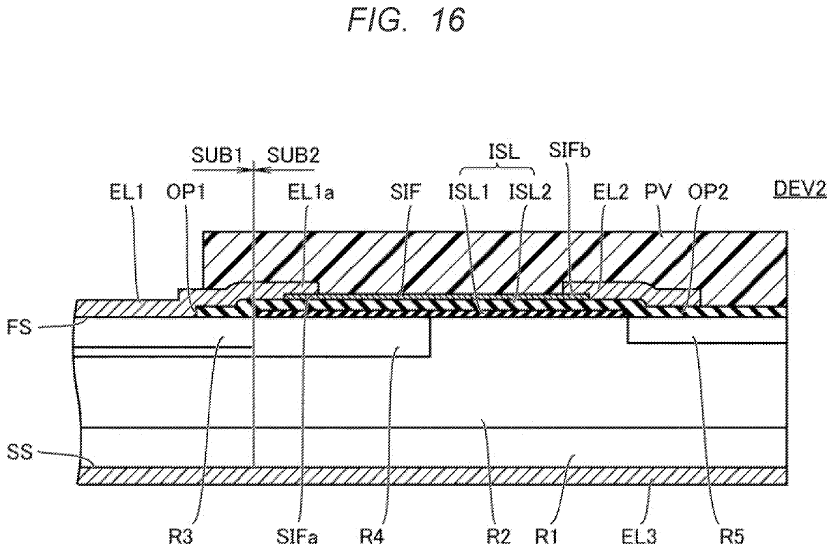

FIG. 16 is a cross-sectional view of a semiconductor device DEV2. FIG. 16 shows a cross section at a position corresponding to II-II in FIG. 1. As shown in FIG. 16, the semiconductor device DEV2 includes a semiconductor substrate SUB, an insulating film ISL, a first electrode EL1 and a second electrode EL2, a semi-insulating film SIF, and a passivation film PV. In the semiconductor device DEV2, the ratio of the number of atoms of silicon to the sum of the number of atoms of silicon and the number of atoms of nitrogen in the semi-insulating film SIF is 0.64 or more. In these respects, the configuration of the semiconductor device DEV2 is the same as that of the semiconductor device DEV1.

In the semiconductor device DEV2, the semi-insulating film SIF is disposed on the insulating film ISL. More specifically, in the semiconductor device DEV2, the semi-insulating film SIF is disposed on the inner side of the step formed on the upper surface of the insulating film ISL. In the semiconductor device DEV2, the semi-insulating film SIF has an inner peripheral edge portion SIFa and an outer peripheral edge portion SIFb. The inner peripheral edge portion SIFa and the outer peripheral edge portion SIFb are respectively covered with the first electrode EL1 and the second electrode EL2. In these respects, the configuration of the semiconductor device DEV2 is different from the configuration of the semiconductor device DEV1.

### Modified Example

In the above description, the ratio of the number of atoms of silicon to the sum of the number of atoms of silicon and the number of atoms of nitrogen in the semi-insulating film SIF is 0.64 or more, but in the semiconductor device DEV2, the ratio of the number of atoms of silicon to the sum of the number of atoms of silicon and the number of atoms of nitrogen in the semi-insulating film SIF may be less than 0.64. In the semiconductor device DEV2, the semi-insulating film SIF may be formed of a material other than a material containing silicon and nitrogen (for example, polycrystalline silicon).

### <Manufacturing Method of the Semiconductor Device DEV2>

A manufacturing method of the semiconductor device DEV2 is described below.

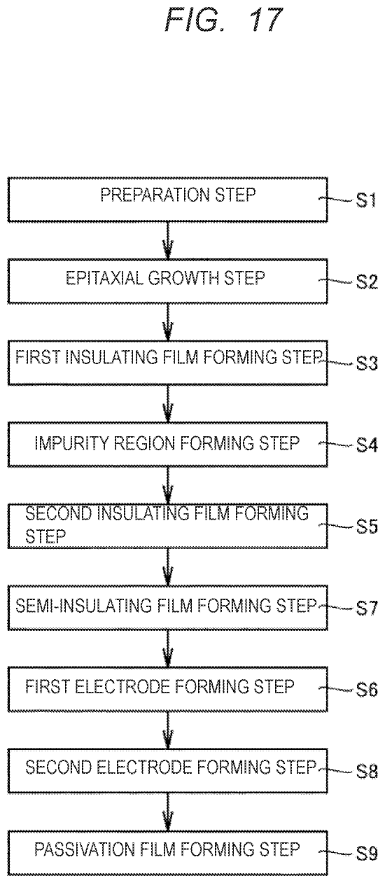

FIG. 17 is a manufacturing process diagram of the semiconductor device DEV2. As shown in FIG. 17, the manufacturing method of the semiconductor device DEV2 includes a preparation step S1, an epitaxial growth step S2, a first insulating film forming step S3, an impurity region forming step S4, a second insulating film forming step S5, a first electrode forming step S6, a semi-insulating film forming step S7, a second electrode forming step S8, and a passivation film forming step S9. In this regard, the manufacturing method of the semiconductor device DEV2 is same as the manufacturing method of the semiconductor device DEV1.

In the manufacturing method of the semiconductor device DEV2, the semi-insulating film forming step S7 is performed after the second insulating film forming step S5. In manufacturing method of the semiconductor device DEV2, the first electrode-forming step S6 is performed after the semi-insulating film-forming step S7. In this regard, the manufacturing method of the semiconductor device DEV2 is different from the manufacturing method of the semiconductor device DEV1.

### <Effect of the Semiconductor Device DEV2>

The advantages of the semiconductor device DEV2 will be described below.

A step is formed in the upper surface of the insulating film ISL. Consequently, in the semiconductor device DEV1, a step is also formed in the upper surface of the first electrode EL1 and the upper surface of the second electrode EL2, and the semi-insulating film SIF may be disposed on the step. Since stress concentration tends to occur in the vicinity of such a step, cracks tend to occur in the semi-insulating film SIF in the semiconductor device DEV1. Since the semi-insulating film SIF becomes brittle as the compositional ratio of the silicon becomes higher, the properties become closer to silicon, and therefore, when the ratio of the number of atoms of the silicon to the sum of the number of atoms of the silicon and the number of atoms of the nitrogen in the semi-insulating film SIF is 0.64 or more, such a crack may occur.

On the other hand, in the semiconductor device DEV2, the inner peripheral edge portion SIFa and the outer peripheral edge portion SIFb are respectively covered with the first electrode EL1 and the second electrode EL2. That is, the semiconductor device DEV2 does not have a portion where the semi-insulating film SIF is disposed on the first electrode EL1 and the second electrode EL2. Therefore, in the semiconductor device DEV2, cracks are less likely to occur in the semi-insulating film SIF without being affected by the step formed on the upper surface of the first electrode EL1 and on the upper surface of the second electrode EL2.

### Third Embodiment

A semiconductor device DEV3 according to a third embodiment will be described. Here, differences from the semiconductor device DEV1 will be mainly described, and redundant description will not be repeated.

### <Configuration of the Semiconductor Device DEV3>

The configuration of the semiconductor device DEV3 will be described below.

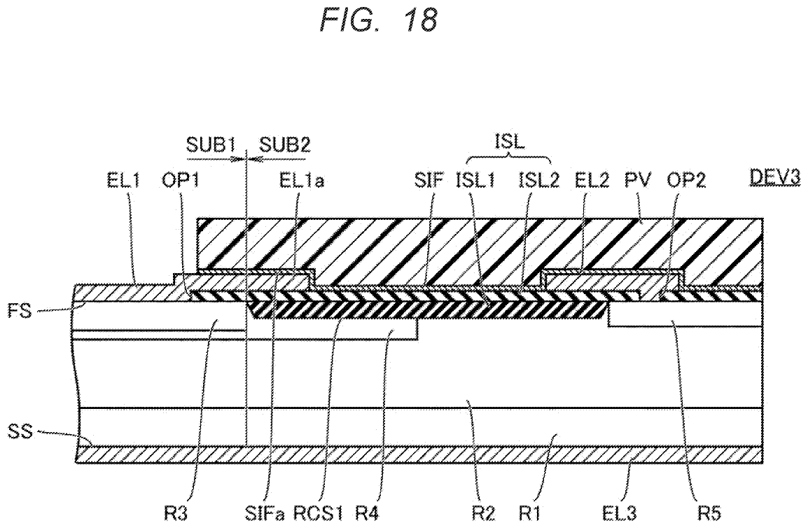

FIG. 18 is a cross-sectional view of a semiconductor device DEV3. FIG. 18 shows a cross section at a position corresponding to II-II in FIG. 1. As shown in FIG. 18, the semiconductor device DEV3 includes a semiconductor substrate SUB, an insulating film ISL, a first electrode EL1 and a second electrode EL2, a semi-insulating film SIF, and a passivation film PV. In the semiconductor device DEV3, the ratio of the number of atoms of silicon to the sum of the number of atoms of silicon and the number of atoms of nitrogen in the semi-insulating film SIF is 0.64 or more. In these respects, the configuration of the semiconductor device DEV3 is the same as that of the semiconductor device DEV1.

In the semiconductor device DEV3, a recess RCS1 is formed on the first surface FS. The first surface FS is recessed toward the second surface SS in the recess RCS1. The recess RCS1 is disposed so as to overlap with the impurity regions R4 in a plan view. The recess RCS1 may extend to an adjacent side of the impurity regions R5. In the semiconductor device DEV3, the first insulating film ISL1 is embedded in the recess RCS1, and the second insulating film ISL2 is disposed on the first surface FS in the termination region SUB2 so as to cover the first insulating film ISL1. In the semiconductor device DEV3, the first insulating film ISL1 is thicker than the second insulating film ISL2, for example. In these respects, the configuration of the semiconductor device DEV3 is different from the configuration of the semiconductor device DEV1.

### Modified Example

In the above description, the ratio of the number of atoms of silicon to the sum of the number of atoms of silicon and the number of atoms of nitrogen in the semi-insulating film SIF is 0.64 or more, but in the semiconductor device DEV3, the ratio of the number of atoms of silicon to the sum of the number of atoms of silicon and the number of atoms of nitrogen in the semi-insulating film SIF may be less than 0.64. In the semiconductor device DEV3, the semi-insulating film SIF may be formed of a material other than a material containing silicon and nitrogen (for example, polycrystalline silicon).

### <Manufacturing Method of the Semiconductor Device DEV3>

A manufacturing method of the semiconductor device DEV3 is described below.

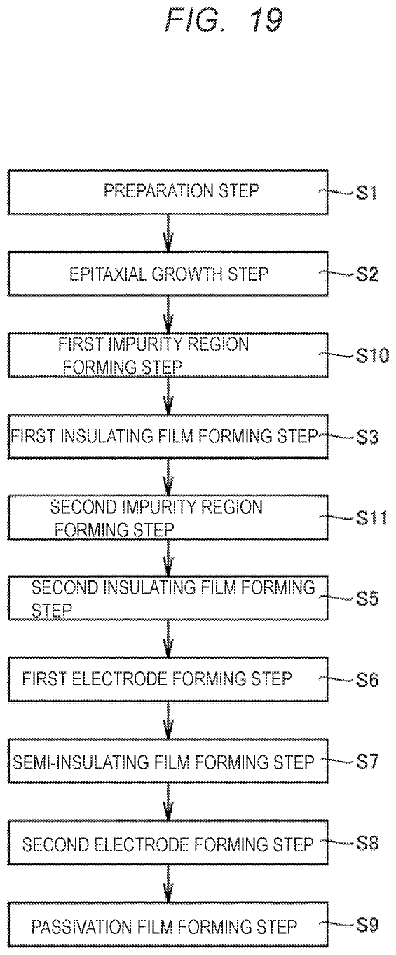

FIG. 19 is a manufacturing process diagram of the semiconductor device DEV3. As shown in FIG. 19, the manufacturing method of the semiconductor device DEV3 includes a preparation step S1, an epitaxial growth step S2, a first insulating film forming step S3, a second insulating film forming step S5, a first electrode forming step S6, a semi-insulating film forming step S7, a second electrode forming step S8, and a passivation film forming step S9. In this regard, the manufacturing method of the semiconductor device DEV3 is the same as the manufacturing method of the semiconductor device DEV1.

The manufacturing method of the semiconductor device DEV3 includes a first impurity region forming step S10 and a second impurity region forming step S11 in place of the impurity region forming step S4.

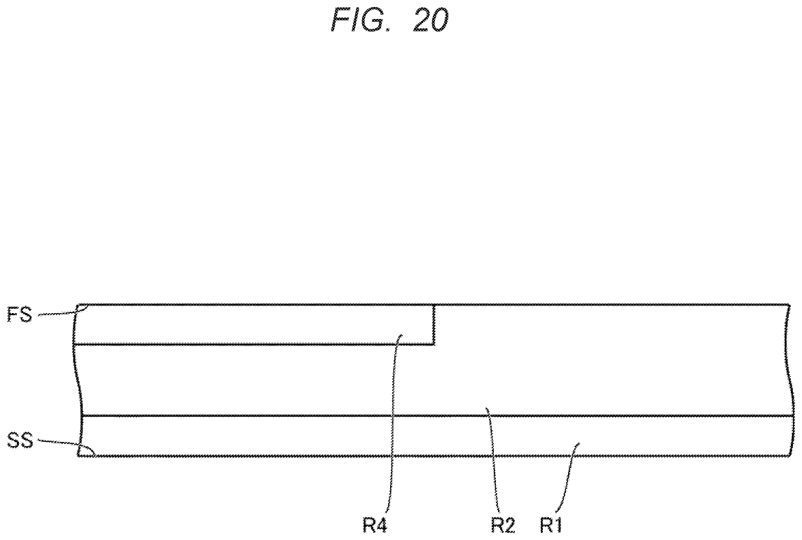

The first impurity-region forming step S10 is performed after the epitaxial growth step S2. FIG. 20 is a cross-sectional view for explaining the first impurity-region forming step S10. As shown in FIG. 20, in the first impurity region forming step S10, the impurity region R4 is formed. In the first impurity-region forming step S10, first, a resist pattern is formed on the first surface FS by photolithography. Second, ion-implantation is performed from the first surface FS side using the resist pattern as a mask. Third, the implanted impurity ions are thermally diffused by annealing the semiconductor substrate SUB.

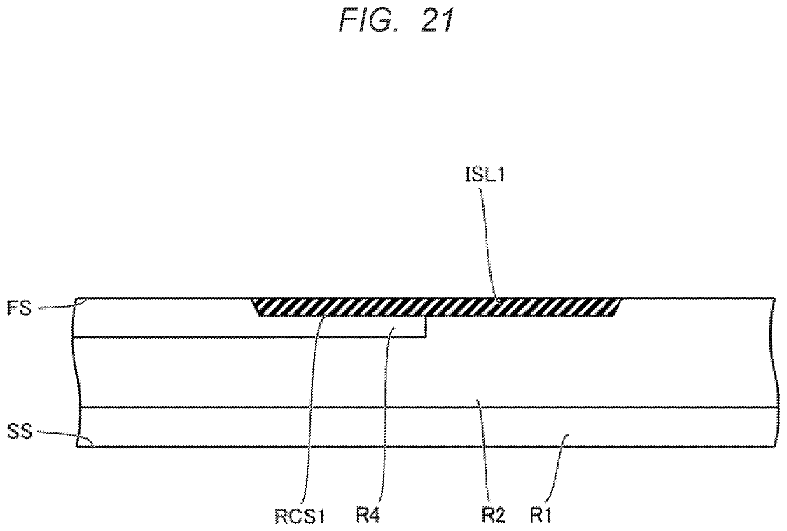

In the manufacturing method of the semiconductor device DEV3, the first insulating film forming step S3 is performed after the first impurity-region forming step S10. FIG. 21 is a cross-sectional view illustrating a first insulating film forming step S3 in the manufacturing method of the semiconductor device DEV3. As shown in FIG. 21, in the manufacturing method of the semiconductor device DEV3, the recess RCS1 and the first insulating film ISL1 are formed in the first insulating film forming step S3. In the first insulating film forming step S3 in the manufacturing method of the semiconductor device DEV2, first, a resist pattern is formed on the first surface FS by photolithography. Second, the first surface FS is etched using the resist pattern as a mask to form a recess RCS1. Third, polycrystalline silicon is partially embedded in the recessed RCS1, for example, by CVD. Fourth, the embedded polycrystalline silicon is thermally oxidized to form a first insulating film ISL1. Note that, when the first insulating film ISL1 protrudes from the recess RCS1, the protruding first insulating film ISL1 may be removed by CMP (Chemical Mechanical Polishing) method. In addition, in the above embodiment, the first insulating film ISL1 is formed by partly embedding the polycrystalline silicon in the recess RCS1 and performing thermal oxidation, but the first insulating film ISL1 may be formed only by thermal oxidation.

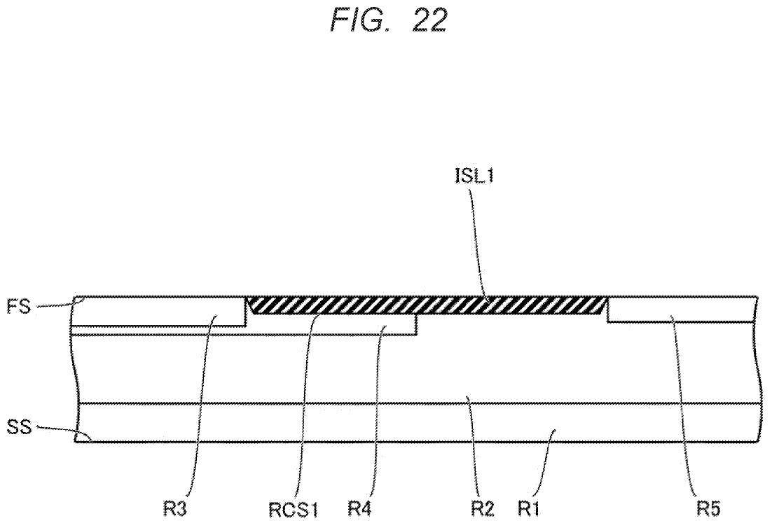

In the manufacturing method of the semiconductor device DEV3, the second impurity-region forming step S11 is performed after the first insulating film forming step S3. FIG. 22 is a cross-sectional view for explaining the second impurity-region forming step S11. As shown in FIG. 22, in the second impurity region forming step S11, the impurity region R3 and the impurity region R5 are formed. In the second impurity-region forming step S11, first, ion-implantation is performed from the first surface FS side with the first insulating film ISL1 being used as a mask. Second, the semiconductor substrate SUB is annealed to thermally diffuse the implanted impurity ions.

In the manufacturing method of the semiconductor device DEV3, after the second impurity region forming step S11, the second insulating film forming step S5, the first electrode forming step S6, the semi-insulating film forming step S7, the second electrode forming step S8, and the passivation film forming step S9 are sequentially performed.

### <Effect of the Semiconductor Device DEV3>

The advantages of the semiconductor device DEV3 will be described below.

In the semiconductor device DEV3, since the first insulating film ISL1 is embedded in the recess RCS1 and the second insulating film ISL2 is disposed so as to cover the first insulating film ISL1, it is less likely that a step is formed on the upper surface of the insulating film ISL and thus on the upper surface of the first electrode EL1 and the second electrode EL2. Therefore, according to the semiconductor device DEV3, cracks due to stress-concentration are less likely to occur in the semi-insulating film SIF even when the semi-insulating film SIF is disposed on the first electrode EL1 and the second electrode EL2.

In the semiconductor device DEV3, the impurity region R4 is formed prior to the formation of the first insulating film ISL1, and thus the ion-implantation for forming the impurity region R4 is performed not via the first insulating film ISL1. Therefore, the semiconductor device DEV3 can reduce the acceleration voltage at the time of ion-implantation for forming the impurity-region R4. Further, in the semiconductor device DEV3, since the first insulating film ISL1 can be used as a mask for ion implantation for forming the impurity region R3 and the impurity region R5, there is no need to separately form a resist pattern for ion implantation for forming the impurity region R3 and the impurity region R5, and thus the process can be simplified.

### Fourth Embodiment

A semiconductor device DEV4 according to a fourth embodiment will be described. Here, differences from the semiconductor device DEV3 will be mainly described, and redundant description will not be repeated.

### <Configuration of the Semiconductor Device DEV4>

The configuration of the semiconductor device DEV4 will be described below.

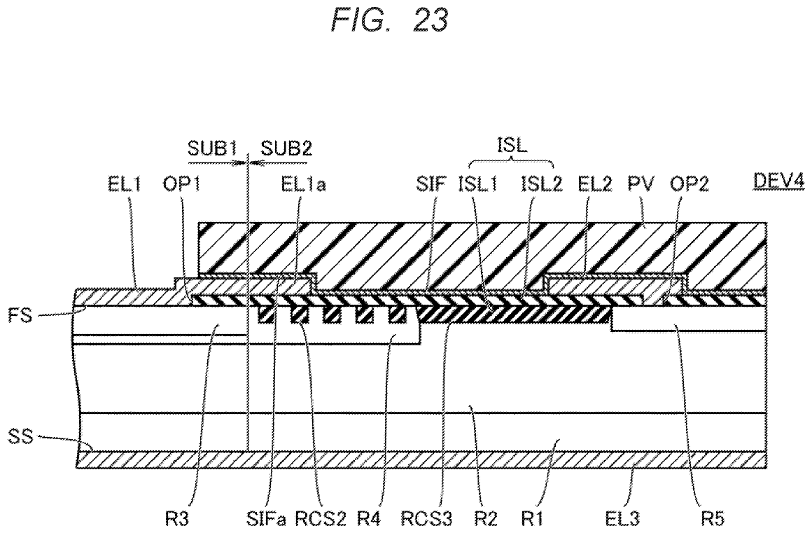

FIG. 23 is a cross-sectional view of a semiconductor device DEV4. FIG. 23 shows a cross section at a position corresponding to II-II in FIG. 1. As shown in FIG. 23, the semiconductor device DEV4 includes a semiconductor substrate SUB, an insulating film ISL, a first electrode EL1 and a second electrode EL2, a semi-insulating film SIF, and a passivation film PV. In the semiconductor device DEV4, the ratio of the number of atoms of silicon to the sum of the number of atoms of silicon and the number of atoms of nitrogen in the semi-insulating film SIF is 0.64 or more. In these respects, the configuration of the semiconductor device DEV4 is the same as that of the semiconductor device DEV3.

In the semiconductor device DEV4, a plurality of recesses RCS2 and a recess RCS3 are formed on the first surface FS. The first surface FS is recessed toward the second surface SS in the recess RCS2 and the recess RCS3. The plurality of recesses RCS2 are arranged so as to overlap with the impurity regions R4 in a plan view. The plurality of recesses RCS2 are spaced apart from each other along a direction from the element region SUB1 toward the termination region SUB2. The recess RCS3 is disposed between the outermost recess RCS2 and the impurity region R5 in a direction from the element region SUB1 toward the termination region SUB2. The recess RCS3 may extend to an adjacent side of the impurity regions R5.

In the semiconductor device DEV4, the first insulating film ISL1 is embedded in each of the plurality of recesses RCS2 and the recesses RCS3, and the second insulating film ISL2 is disposed on the first surface FS in the termination region SUB2 so as to cover the insulating first film ISL1. In these respects, the configuration of the semiconductor device DEV4 is different from the configuration of the semiconductor device DEV3.

### Modified Example

In the above description, the ratio of the number of atoms of silicon to the sum of the number of atoms of silicon and the number of atoms of nitrogen in the semi-insulating film SIF is 0.64 or more, but in the semiconductor device DEV4, the ratio of the number of atoms of silicon to the sum of the number of atoms of silicon and the number of atoms of nitrogen in the semi-insulating film SIF may be less than 0.64. In the semiconductor device DEV4, the semi-insulating film SIF may be formed of a material other than and nitrogen a material containing silicon (for example, polycrystalline silicon).

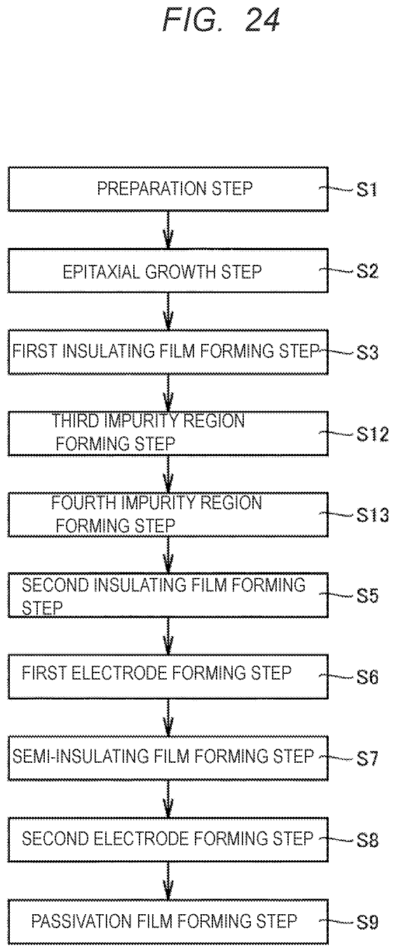

FIG. 24 is a manufacturing process diagram of the semiconductor device DEV4. As shown in FIG. 24, the manufacturing method of the semiconductor device DEV4 includes a preparation step S1, an epitaxial growth step S2, a first insulating film forming step S3, a second insulating film forming step S5, a first electrode forming step S6, a semi-insulating film forming step S7, a second electrode forming step S8, and a passivation film forming step S9. In this regard, the manufacturing method of the semiconductor device DEV4 is the same as the manufacturing method of the semiconductor device DEV3.

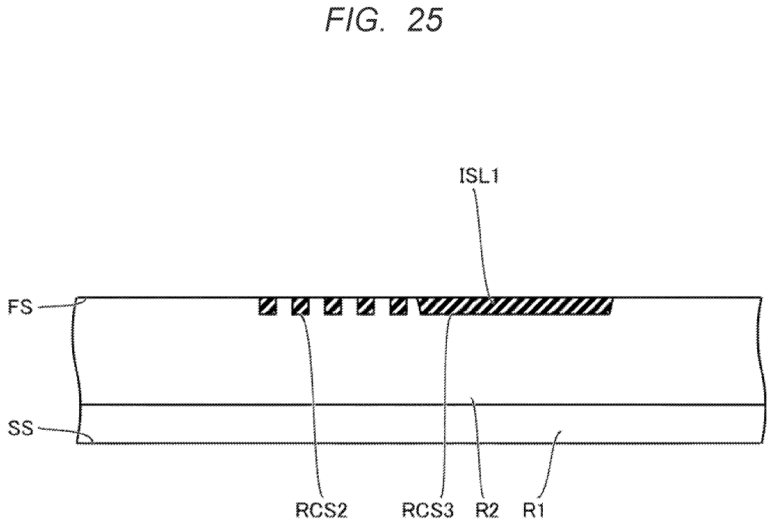

In the manufacturing method of the semiconductor device DEV4, the first insulating film forming step S3 is performed after the epitaxial growth step S2. FIG. 25 is a cross-sectional view illustrating a first insulating film forming step S3 in the manufacturing method of the semiconductor device DEV4. As shown in FIG. 25, in the manufacturing method of the semiconductor device DEV4, a plurality of recesses RCS2, a recess RCS3, and a first insulating film ISL1 are formed in the first insulating film forming step S3.

In the first insulating film forming step S3 in the manufacturing method of the semiconductor device DEV4, first, a resist pattern is formed on the first surface FS by photolithography. Second, a plurality of recesses RCS2 and a recess RCS3 are formed by etching the first surface FS using the resist pattern as a mask. Third, polycrystalline silicon is partially embedded in the plurality of recesses RCS2 and the recess RCS3, for example, by CVD method. Fourth, the embedded polycrystalline silicon is thermally oxidized to form a first insulating film ISL1. Note that the protruding first insulating film ISL1 may be removed by CMP method when the first insulating film ISL1 protrudes from the recess RCS1.

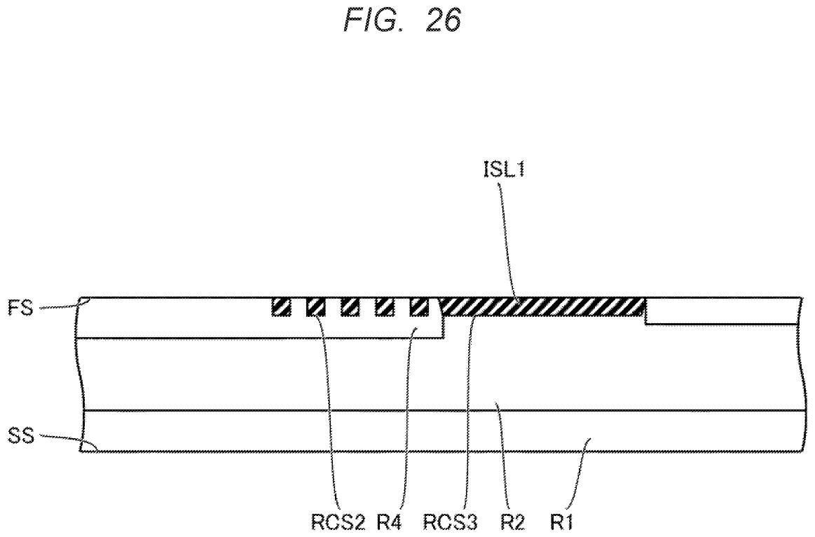

The manufacturing method of the semiconductor device DEV4 has a third impurity region forming step S12 instead of the first impurity region forming step S10. The third impurity-region forming step S12 is performed after the first insulating film forming step S3. FIG. 26 is a cross-sectional view for explaining the third impurity-region forming step S12. As shown in FIG. 26, in the third impurity region forming step S12, the impurity region R4 is formed. In the third impurity-region forming step S12, first, ion-implantation is performed from the first surface FS side with the first insulating film ISL1 being used as a mask. As a result, impurity ions are implanted between two adjacent recesses RCS2. Third, the implanted impurity ions are thermally diffused by annealing the semiconductor substrate SUB.

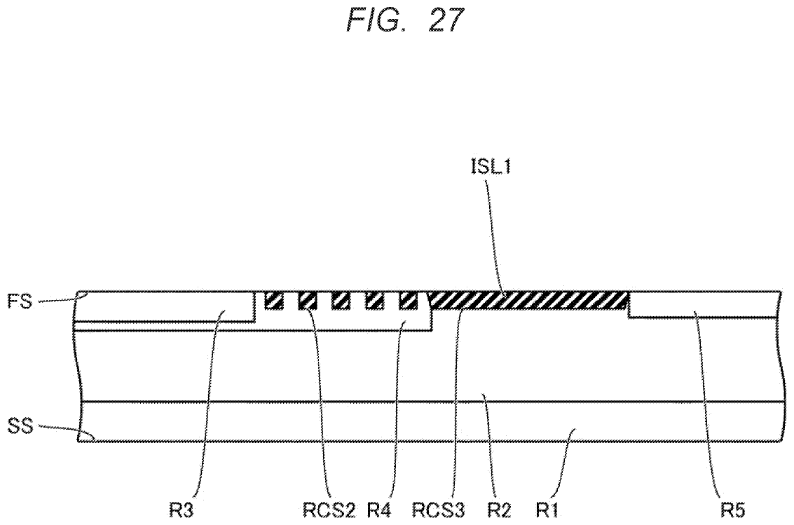

The manufacturing method of the semiconductor device DEV4 has a fourth impurity region forming step S13 instead of the second impurity region forming step S11. The fourth impurity region forming step S13 is performed after the third impurity region forming step S12. FIG. 27 is a cross-sectional view illustrating the fourth impurity-region forming step S13. As shown in FIG. 27, in the fourth impurity region forming step S13, the impurity region R3 and the impurity region R5 are formed. First, in the fourth impurity-region forming step S13, a resist pattern is formed on the first surface FS by photolithography. Second, ion-implantation is performed from the first surface FS side using the resist pattern as a mask. Third, the implanted impurity ions are thermally diffused by annealing the semiconductor substrate SUB.

In the manufacturing method of the semiconductor device DEV4, the second insulating film forming step S5, the first electrode forming step S6, the semi-insulating film forming step S7, the second electrode forming step S8, and the passivation film forming step S9 are sequentially performed after the fourth impurity region forming step S13.

In the semiconductor device DEV4, since the first insulating film ISL1 is embedded in the recesses RCS2 and the recess RCS3 and the second insulating film ISL2 is disposed so as to cover the first insulating film ISL1, it is less likely that a step is formed on the upper surface of the insulating film ISL and thus on the upper surface of the first electrode EL1 and the second electrode ISL2. Therefore, according to the semiconductor device DEV4, cracks due to stress-concentration are less likely to occur in the semi-insulating film SIF even when the semi-insulating film SIF is disposed on the first electrode EL1 and the second electrode EL2.

In the semiconductor device DEV3, ion-implantation for forming the impurity regions R4 is performed between two adjacent recesses RCS2 without the first insulating film ISL1 interposed therebetween. Therefore, the semiconductor device DEV3 can reduce the acceleration voltage at the time of ion-implantation for forming the impurity-region R4. In the semiconductor device DEV4, since the impurity region R4 can be formed using the first insulating film ISL1 as a mask at the time of ion implantation, it is unnecessary to separately form a resist pattern for ion implantation for forming the impurity region R4, and thus the process can be simplified.

Although the invention made by the present inventors has been described in detail based on the embodiments, it is needless to say that the present invention is not limited to the above-described embodiments and can be variously modified without departing from the gist thereof.

What is claimed is:

1. A semiconductor device comprising:
a semiconductor substrate;
an insulating film;
a first electrode and a second electrode; and
a semi-insulating film,
wherein the semiconductor substrate includes a first surface;
wherein the semiconductor substrate includes, in plan view, an element region and a termination region surrounding the element region;
wherein the semiconductor substrate includes a first impurity region formed on the first surface in the termination region;
wherein the insulating film covers the first surface in the termination region;
wherein the first electrode is electrically connected to the first impurity region, and faces the first impurity region with the insulating film interposed therebetween;
wherein the second electrode is disposed on the insulating film so as to surround the first electrode while being spaced apart from the first electrode in a plan view;
wherein the semi-insulating film is disposed so as to extend across the insulating film between the first electrode and the second electrode in a plan view;
wherein the semi-insulating film includes silicon and nitrogen;
wherein the ratio of the number of atoms of silicon to the sum of the number of atoms of silicon and the number of atoms of nitrogen in the semi-insulating film is 0.64 or more.

2. The semiconductor device according to claim 1, wherein the ratio of the number of atoms of silicon to the sum of the number of atoms of silicon and the number of atoms of nitrogen in the semi-insulating film is 0.74 or less.

3. The semiconductor device according to claim 1, wherein some of the silicon is bonded to hydrogen in the semi-insulating film.

4. The semiconductor device according to claim 1, wherein the semi-insulating film is a mixed crystal of silicon nitride and amorphous silicon.

5. The semiconductor device according to claim 1, wherein a thickness of the semi-insulating film is not less than 50 nm and not more than 1000 nm.

6. The semiconductor device according to claim 1, wherein a thickness of the insulating film is 0.5 micrometers or more and 3.0 micrometers or less.

7. The semiconductor device according to claim 1, wherein the first electrode and the second electrode are electrically connected by the semi-insulating film.

8. The semiconductor device according to claim 1,
wherein the semiconductor substrate includes a second impurity region formed on the first surface of the element region;
wherein the first electrode is connected to the second impurity region;
wherein an impurity concentration in the second impurity region is higher than an impurity concentration in the first impurity region.

9. The semiconductor device according to claim 1, further comprising a passivation film formed to cover the semi-insulating film.

10. The semiconductor device according to claim 1,
wherein the first electrode has an outer peripheral edge portion;
wherein the semi-insulating film has an inner peripheral edge portion;
wherein the semi-insulating film covers the second electrode; and
wherein the inner peripheral edge portion covers the outer peripheral edge portion.

11. The semiconductor device according to claim 1,
wherein the semi-insulating film has an inner peripheral edge portion and an outer peripheral edge portion; and
wherein the first electrode and the second electrode respectively cover the inner peripheral edge portion and the outer peripheral edge portion.

12. The semiconductor device according to claim 1,
wherein the semiconductor substrate includes a second surface opposite the first surface in a direction of thickness of the semiconductor substrate;
wherein in the first surface, so as to overlap with the first impurity region in plan view, a first recess recessed toward the second surface is formed; and
wherein the insulating film includes a first insulating film embedded in the first recess and a second insulating film disposed on the first surface so as to cover the first insulating film.

13. The semiconductor device according to claim 12, wherein the first insulating film is thicker than the second insulating film.

14. The semiconductor device according to claim 1,
wherein the semiconductor substrate includes a second surface opposite the first surface in a direction of thickness of the semiconductor substrate;
wherein in the first surface, so as to overlap the first impurity region in plan view, a plurality of second recesses recessed toward the first surface are formed;
wherein the plurality of second recesses are spaced apart along a direction from the element region toward the termination region; and
wherein the insulating film includes a first insulating film embedded in each of the plurality of second recesses, and a second insulating film disposed on the first surface so as to cover the first insulating film.

15. The semiconductor device according to claim 1, wherein an FRD is formed in the element region.

16. The semiconductor device according to claim 1, wherein an IGBT is formed in the element region.
